(19) United States
(12) Patent Application Publication
(10) Pub. No.: US 2017/0125647 A1
(43) Pub. Date: May 4, 2017

(54) LIGHT-EMITTING DIODE PACKAGE AND METHOD OF MANUFACTURING THE SAME

(71) Applicant: Samsung Electronics Co., Ltd., Suwon-si (KR)

(72) Inventors: HUN-YONG PARK, Seoul (KR); Choo-ho KIM, Yongin-si (KR); Song-ho JEONG, Hwaseong-si (KR); Jong-ho LIM, Suwon-si (KR)

(73) Assignee: Samsung Electronics Co., Ltd., Suwon-si (KR)

(21) Appl. No.: 15/216,137

(22) Filed: Jul. 21, 2016

(30) Foreign Application Priority Data
Nov. 2, 2015 (KR) 10-2015-0153258

(51) Int. Cl. H01L 33/50; H01L 33/30; H01L 33/38

(52) U.S. Cl. CPC H01L 33/505; H01L 33/382; H01L 33/30; H01L 33/56

(57) ABSTRACT

A light-emitting diode (LED) package includes an LED chip, a phosphor film adhered to a top surface of the LED chip, and a molding phosphor covering a side surface of the LED chip.

### CROSS-REFERENCE TO RELATED APPLICATION

This application claims priority under 35 U.S.C. §119 to Korean Patent Application No. 10-2015-0153258, filed on Nov. 2, 2015, in the Korean Intellectual Property Office, the disclosure of which is incorporated herein in its entirety by reference.

### BACKGROUND

The present disclosure relates to a light-emitting diode (LED) package and a method of manufacturing the same, and more particularly, to an LED package including a phosphor structure capable of improving a color deviation of light, and a method of manufacturing the LED package.

In general, an LED package may be manufactured by mounting an LED chip on a lead frame substrate. Since a size of the LED package including the lead frame substrate increases due to an additional substrate, the total manufacturing cost may increase. Thus, the demand for chip-scale packages (CSPs) has recently increased, and research into techniques of improving optical quality of an LED package manufactured on a chip scale has progressed.

### SUMMARY

Inventive concepts relate to a light-emitting diode (LED) package capable of reducing a color deviation of light emitted by the LED package and improving optical quality, and a method of manufacturing the LED package.

According to example embodiments of inventive concepts, an LED package including a LED chip, a phosphor film on a top surface of the LED chip, and a molding phosphor covering a side surface of the LED chip.

In example embodiments, the phosphor film and the molding phosphor film may be configured to convert light generated by the LED chip into white light, and the LED chip may be configured to emit light omnidirectionally.

In example embodiments, the phosphor film and the molding phosphor may include identical phosphor materials.

In example embodiments, an interface may be between the molding phosphor and the phosphor film.

In example embodiments, a thickness of the molding phosphor located on the side surface of the LED chip may be 1 to 2 times as large as a thickness of the phosphor film.

In example embodiments, the LED chip may include a light-emitting structure and an electrode. A bottom surface of the light-emitting structure may be on the electrode, and the molding phosphor may extend towards a sidewall of the electrode.

In example embodiments, a level of a bottom surface of the molding phosphor may extend below the light emitting structure, and a bottom surface of the light-emitting structure may be on the molding phosphor.

In example embodiments, the phosphor film may cover a top surface of the molding phosphor located on the top surface and the side surface of the LED chip.

In example embodiments, the molding phosphor may surround a side surface of the phosphor film.

In example embodiments, an area of the phosphor film may be less than an area of the LED chip, and the molding phosphor may surround an outer side surface of the phosphor film and may cover the top surface of the LED chip.

In example embodiments, the LED package may further include an adhesive layer between the LED chip and the phosphor film.

According to example embodiments of inventive concepts, a LED package includes a LED chip; a phosphor film on a portion of a top surface of the LED chip, an area of the phosphor film being smaller than an area of the top surface of the LED chip; and a molding body covering a remaining portion of the top surface of the LED chip that is not covered with the phosphor film, a side surface of the LED chip, and a side surface of the phosphor film.

In example embodiments, the molding body may include a white resin.

In example embodiments, the molding body may include reflective powder.

In example embodiments, the top surface of the LED chip may be divided into a first region overlapping the phosphor film and a second region overlapping the molding body. The LED chip may be configured to emit light through only the first region.

According to example embodiments, a LED package includes a LED chip; a phosphor film on a top surface of the LED chip; and a molding structure connected to a side surface of the LED chip.

In example embodiments, the LED chip may further include electrodes connected to the LED chip. The molding structure may be a molding phosphor that contacts side surfaces and a bottom surface of the LED chip. The molding phosphor may define openings that expose the LED chip. The electrodes may be connected to the LED chip through the openings. The phosphor film and the molding phosphor may be configured to convert light generated by the LED chip into white light. The phosphor film may extend onto a top surface of the molding phosphor. A thickness of the phosphor film may be uniform.

In example embodiments, the LED chip may further include electrodes connected to the LED chip. The molding structure may be a molding phosphor that contacts side surfaces and a bottom surface of the LED chip. The molding phosphor may define openings that expose the LED chip. The electrodes may be connected to the LED chip through the openings. The phosphor film and the molding phosphor may be configured to convert light generated by the LED chip into white light. An area of the phosphor film may be greater than an area of the top surface of the LED chip. A thickness of the phosphor film may be uniform.

In example embodiments, the LED chip may further include electrodes connected to the LED chip. The molding structure may be a molding body covering a remaining portion of the top surface of the LED chip, a side surface of the LED chip, and a side surface of the phosphor film. The molding body may define openings that expose the LED chip. The electrodes may be connected to the LED chip through the openings. The phosphor film may be configured to convert light generated by the LED chip into white light. An area of the phosphor film may be less than an area of the top surface of the LED chip. A thickness of the phosphor film may be uniform.

In example embodiments, the LED chip may further include a wavelength conversion material.

### BRIEF DESCRIPTION OF THE DRAWINGS

Example embodiments of inventive concepts will be more clearly understood from the following detailed description taken in conjunction with the accompanying drawings in which:

FIG. 1A is a perspective view of a light emitting diode (LED) package according to example embodiments;

FIG. 1B is a cross-sectional view taken along a line I-I of FIG. 1A;

FIG. 1C is an enlarged view of a region A of FIG. 1B;

FIG. 1D is an enlarged view of a region B of FIG. 1B;

FIG. 2A is a perspective view of an LED package according to example embodiments;

FIG. 2B is a cross-sectional view taken along a line II-II of FIG. 2A;

FIG. 3A is a perspective view of an LED package according to example embodiments;

FIG. 3B is a cross-sectional view taken along a line III-III of FIG. 3A;

FIG. 4 is a flowchart of process operations of a method of manufacturing the LED package shown in FIGS. 1A to 3B;

FIGS. 5A to 5D are cross-sectional views of process operations of a method of manufacturing the LED package shown in FIGS. 1A and 1B;

FIG. 6 is a cross-sectional view of process operations of a method of manufacturing the LED package shown in FIGS. 2A and 2B;

FIG. 7 is a cross-sectional view of process operations of a method of manufacturing the LED package shown in FIGS. 3A and 3B;

FIG. 8 is a graph showing a Planckian spectrum;

FIGS. 9A and 9B show white light-emitting package modules including LED packages manufactured according to example embodiments;

FIG. 10 shows types of phosphors according to applications included in a white LED package using a blue LED chip (about 440 nm to about 460 nm);

FIG. 11 is an exploded perspective view of a backlight (BL) assembly including an LED package according to example embodiments or an electronic device;

FIG. 12 is a schematic diagram of a flat-panel semiconductor light-emitting apparatus including an LED array unit and an LED module in which an LED according to example embodiments is arranged;

FIG. 13 is a schematic diagram of a bulb-type lamp, which is a semiconductor light-emitting apparatus including an LED array unit and an LED module in which an LED according to example embodiments is arranged; and

FIGS. 14 and 15 are diagrams of examples of applying a lighting system using an LED package according to example embodiments or an electronic device to a home network.

### DETAILED DESCRIPTION OF EXAMPLE EMBODIMENTS

Example embodiments may be embodied in many different forms and should not be construed as being limited to the embodiments set forth herein; rather, these embodiments are provided so that this disclosure will be thorough and complete, and will fully convey the scope of inventive concepts to those of ordinary skill in the art. As used herein, the term “and/or” includes any and all combinations of one or more of the associated listed items. Expressions such as “at least one of” when preceding a list of elements, modify the entire list of elements and do not modify the individual elements of the list.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein, the term “and/or” includes any and all combinations of one or more of the associated listed items. Expressions such as “at least one of,” when preceding a list of elements, modify the entire list of elements and do not modify the individual elements of the list.

It will be understood that, although the terms “first”, “second”, etc. may be used herein to describe various elements, components, regions, layers and/or sections. These elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

When example embodiments may be embodied otherwise, respective process steps described herein may be performed otherwise. For example, two process steps described in a sequential order may be performed substantially the same time or in reverse order.

The terminology used herein is for the purpose of describing particular embodiments only and is not intended to be limiting of inventive concepts. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless explicitly so defined herein.

The same reference numerals are used to denote the same elements in the drawings, and repeated descriptions thereof are simplified or omitted for brevity. Since sizes or thicknesses of various elements and regions are exaggerated in the drawings, inventive concepts are not limited by relative sizes or intervals.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

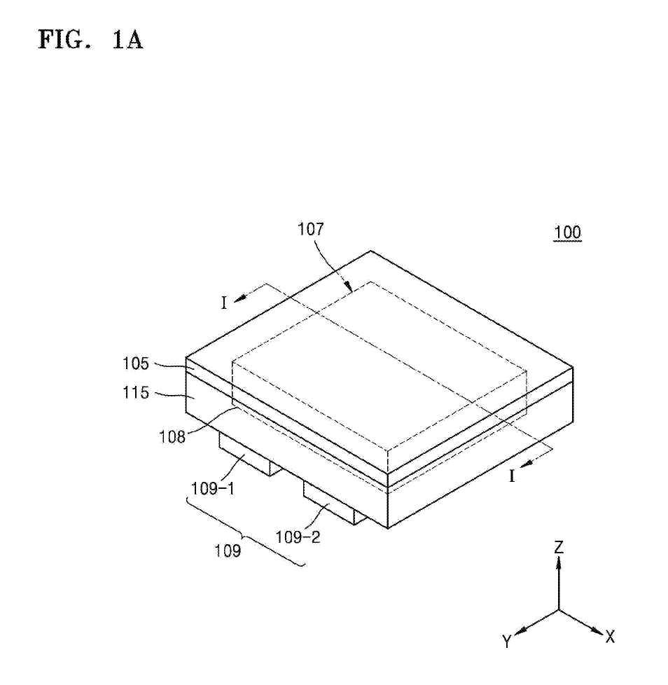

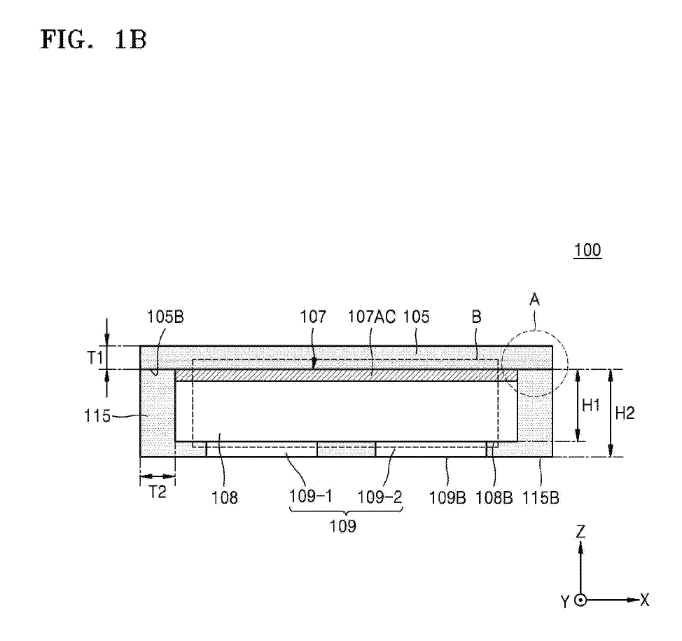

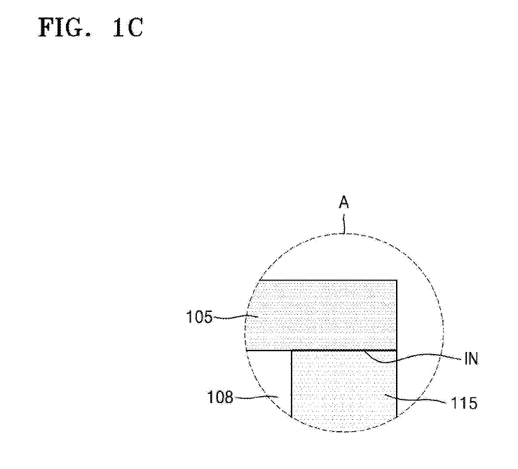

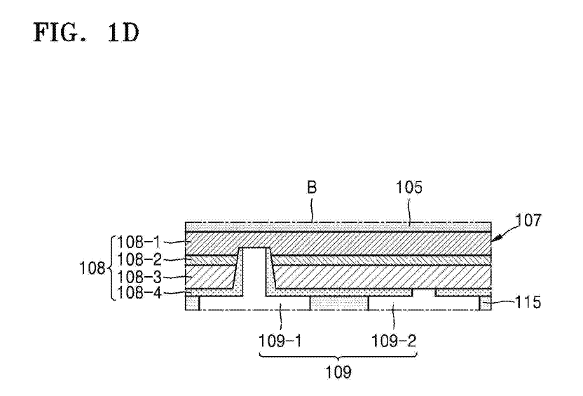

FIG. 1A is a perspective view of a light-emitting diode (LED) package 100 according to example embodiments. FIG. 1B is a cross-sectional view taken along a line I-I of FIG. 1A. FIG. 1C is an enlarged view of a region A of FIG. 1B, and FIG. 1D is an enlarged view of a region B of FIG. 1B.

Referring to FIGS. 1A and 1B, the LED package 100 may include an LED chip 107, a phosphor film 105 adhered to the LED chip 107, and a molding phosphor 115 that covers a side surface of the LED chip 107. Light generated by the LED chip 107 may be converted into white light by the phosphor film 105 and the molding phosphor 115 and emitted omnidirectionally. The phosphor film 105 may have a bottom surface 105B. The

A volume of the LED package 100 may increase by as much as a thickness T2 of the molding phosphor 115 in a horizontal direction (X direction and Y direction) from the LED chip 107 and increase by as much as a thickness T1 of the phosphor film 105 in a vertical direction (Z direction) from the LED chip 107. That is, the LED package 100 may be a subminiature chip-scale package (CSP) having a similar volume to the volume of the LED chip 107.

In the LED package 100, the phosphor film 105 having a uniform thickness may be adhered to a top surface of the LED chip 107, thereby reducing a color deviation of light emitted through the top surface of the LED chip 107. Simultaneously, the molding phosphor 115 may be located on a side surface and a bottom surface of the LED chip 107 by molding a flowable phosphor material. Then, all surfaces through which light emitted may be coated with a phosphor material. Thus, emission (or light leakage) of unconverted light may be limited (and/or prevented), and optical efficiency may be improved.

Specifically, the LED chip 107 may include a light-emitting structure 108 and an electrode 109 on a bottom surface of the light-emitting structure 108. Most light generated by the light-emitting structure 108 may be emitted through a main surface MS of the light-emitting structure 108. The main surface MS is opposite to a surface of the light-emitting structure 108 on which the electrode 109 is formed. Although the main surface MS is illustrated on a portion of the light-emitting structure 108 in FIG. 1B for clarity, the main surface MS may not be an element independent from the light-emitting structure 108. Hereinafter, the main surface MS of the light-emitting structure 108 will be referred to as a top surface of the light-emitting structure 108. The surface of the light-emitting structure 108 that is on the electrode 109 will be referred to as a bottom surface of the light-emitting structure 108.

Referring to FIGS. 1A, 1B, and 1D, the light-emitting structure 108 may include a stack structure. The stack structure may include a first-conductivity-type semiconductor layer 108-1, an active layer 108-2, and a second-conductivity-type semiconductor layer 108-3. The first-conductivity-type semiconductor layer 108-1 may include a p-type doped semiconductor, and the second-conductivity-type semiconductor layer 108-3 may include an n-type doped semiconductor. Conversely, the first-conductivity-type semiconductor layer 108-1 may include an n-type doped semiconductor, and the second-conductivity-type semiconductor layer 108-3 may include a p-type doped semiconductor. The first and second-conductivity-type semiconductor layers 108-1 and 108-3 may include a nitride semiconductor, for example, AlₓIn_{y}Ga_{(1-x-y})N (0<x<1, 0<y<1, 0<x+y<1). Alternatively, the first and second-conductivity-type semiconductor layers 108-1 and 108-3 may include a GaAs-based semiconductor or a GaP-based semiconductor instead of the nitride semiconductor. Each of the first-conductivity-type semiconductor layer 108-1, the active layer 108-2, and the second-conductivity-type semiconductor layer 108-3 may be an epitaxial layer.

Although not shown, the phosphor film 105 may be formed on a rough portion of the light-emitting structure 108. The rough portion may effectively extract light from the light-emitting structure 108 and may improve optical efficiency. The rough portion may be formed during a process of removing a growth substrate adopted to form the light-emitting structure 108.

The active layer 108-2 between the first and second-conductivity-type semiconductor layers 108-1 and 108-2 may emit light having a desired (and/or alternatively predetermined) energy through a recombination of electrons and holes. The active layer 108-2 may have a multi-quantum well (MQW) structure (e.g., an InGaN/GaN structure or an AlGaN/GaN structure) in which a quantum well layer and a quantum barrier layer are alternately stacked. Alternatively, the active layer 108-2 may have a single quantum well (SQW) structure. The light-emitting structure 108 may emit blue light, green light, red light, or ultraviolet (UV) light depending on a material of a compound semiconductor included in the light-emitting structure 108. However, a wavelength conversion layer may be further located on the light-emitting structure 108 and convert the wavelength of light generated by the light-emitting structure 108 and emit light in various colors.

The first and second-conductivity-type semiconductor layers 108-1 and 108-3 may be connected to first and second electrodes 109-1 and 109-2, respectively. The first-conductivity-type semiconductor layer 108-1 may be exposed by a through hole that penetrates the second-conductivity-type semiconductor layer 108-3 and the active layer 108-2. The first electrode 109-1 may be formed in a space defined by an insulating layer 108-4 within the through hole and connected to the first-conductivity-type semiconductor layer 108-1. The insulating layer 108-4 may be located on an inner sidewall of the through hole and a bottom surface of the second-conductivity-type semiconductor layer 108-3 and limit (and/or prevent) electrical connection of the first electrode 109-1 with the active layer 108-2 and the second electrode 109-2. Also, the second-conductivity-type semiconductor layer 108-3 may be connected to the second electrode 109-2 through the insulating layer 108-4 on the second-conductivity-type semiconductor layer 108-3.

Side surfaces of the first and second electrodes 109-1 and 109-2 may be covered with the molding phosphor 115, while bottom surfaces of the first and second electrodes 109-1 and 109-2 may be exposed. The bottom surfaces of the first and second electrodes 109-1 and 109-2 may be electrically connected to a substrate (not shown) on which the LED package 100 is mounted.

Although the first and second electrodes 109-1 and 109-2 are on one surface of the light-emitting structure 108, electrodes having only one polarity may be provided on one surface of the light-emitting structure 108 according to a structure of the LED chip 107. Alternatively, at least two electrodes having at least one polarity may be provided on one surface of the light-emitting structure 108. The first and second electrodes 109-1 and 109-2 may have various shapes.

In example embodiments, the first and second electrodes 109-1 and 109-2 may include a conductive material such as a metal and/or metal alloy. For example, the first and second electrodes 109-1 and 109-2 may include silver (Ag), nickel (Ni), aluminum (Al), rhodium (Rh), palladium (Pd), iridium (Jr), ruthenium (Ru), magnesium (Mg), zinc (Zn), platinum (Pt), gold (Au), alloys thereof, and/or combinations thereof. Each of the first and second electrodes 109-1 and 109-2 may have a structure including at least two layers, such as Ni/Ag, Zn/Ag, Ni/Al, Zn/Al, Pd/Ag, Pd/Al, Ir/Ag, Ir/Au, Pt/Ag, Pt/Al, or Ni/Ag/Pt. In example embodiments, each of the first and second electrodes 109-1 and 109-2 may include a seed layer including a material such as nickel (Ni) or chromium (Cr), and include an electrode material (e.g., Au) formed by using a plating process.

The first-conductivity-type semiconductor layer 108-1, the active layer 108-2, the second-conductivity-type semiconductor layer 108-3, the insulating layer 108-4, the first electrode 109-1, and second electrode 109-2 shown in FIG. 1D show an example of an electrical connection structure of the light-emitting structure 108 and the electrode 109, but inventive concepts are not limited thereto. In example embodiments, the light-emitting structure 108 may be an arbitrary element configured to emit light having desired (and/or alternatively predetermined) energy, and the electrode 109 may have various structures configured to transmit energy to the light-emitting structure 108.

The phosphor film 105 may be adhered to the top surface of the LED chip 107. The phosphor film 105 may have a sheet shape having a uniform thickness over the entire surface of the LED chip 107. The phosphor film 105 may cover the entire top surface of the LED chip 107. In this case, the phosphor film 105 may cover the top surface of the molding phosphor 115 on the side surface of the LED chip 107. That is, the phosphor film 105 may cover the entire top surface of the LED package 100.

The phosphor film 105 may be excited by light emitted by the LED chip 107 and convert at least part of the light into light having a different wavelength than the light emitted by the LED chip 107. For example, when the LED chip 107 generates blue light, the blue light generated by the LED chip 107 may be wavelength-converted into white light by a wavelength conversion material contained in the phosphor film 105.

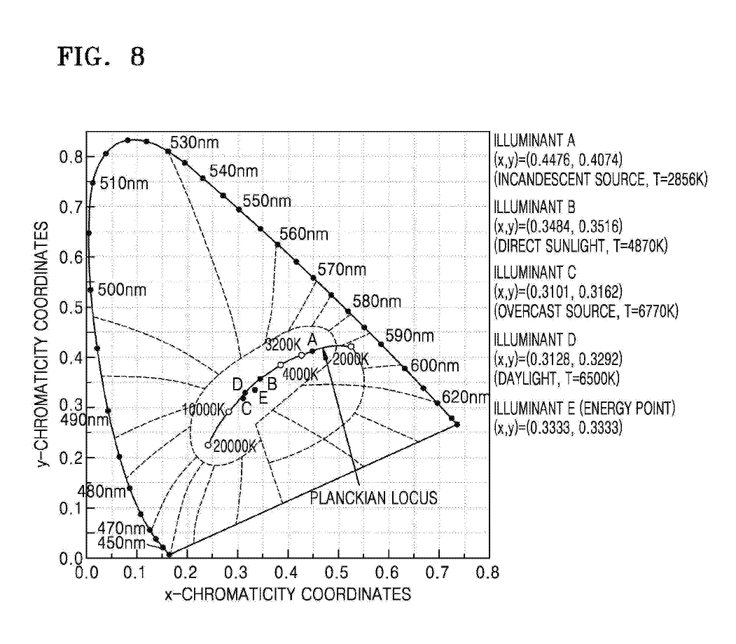

The phosphor film 105 may include a resin containing a wavelength conversion material. For example, the wavelength conversion material may be a phosphor material, and the resin may be a silicone resin, an epoxy resin, or a resin mixture thereof. The phosphor film 105 may have electrical insulating characteristics. The wavelength conversion material may include at least two kinds of materials capable of providing light having different wavelengths. Also, the phosphor film 105 may have a structure formed by stacking a plurality of wavelength conversion layers. For example, the phosphor film 105 may have a structure formed by stacking a first wavelength conversion layer configured to output green light and a second wavelength conversion layer configured to output red light. A specific material included in the phosphor film 105 will be described in detail with reference to FIGS. 8 to 10.

Since the phosphor film 105 has a uniform thickness over the entire surface thereof, even if light generated by the LED chip 107 is emitted to any position of the phosphor film 105, light of uniform color may be obtained, thereby improving optical quality.

In example embodiments, an adhesive layer 107AC may be further formed between the top surface of the LED chip 107 and the phosphor film 105. The LED chip 107 may be tightly adhered to the phosphor film 105 by the adhesive layer 107AC.

The molding phosphor 115 may define the side surface of the LED chip 107, the bottom surface of the phosphor film 105, and the electrode 109 and cover the bottom surface of the light-emitting structure 108. Since the molding phosphor 115 is formed by molding a flowable phosphor material, all exposed surfaces of the light-emitting structure 108 may be covered with the molding phosphor 115 without being affected by the phosphor film 105 and the rough portion formed on the light-emitting structure 108 (e.g., a structure of the electrode 109).

Referring to FIG. 1C, an interface IN may be formed between the bottom surface of the phosphor film 105 and the top surface of the molding phosphor 115. Even if the molding phosphor 115 includes the same material as the phosphor film 105, the interface IN may occur due to a difference in stiffness between the phosphor film 105 and the molding phosphor 115. In example embodiments, an interfacial debonding structure may be formed at the interface IN between the bottom surface of the phosphor film 105 and the molding phosphor 115.

The thickness T2 of the molding phosphor 115 on the side surface of the LED chip 107 may be 1 to 2 times as large as the thickness T1 of the phosphor film 105, but inventive concepts are not limited thereto. The thickness T2 of the molding phosphor 115 may be substantially equal to the thickness T1 of the phosphor film 105, thereby reducing a color deviation between light emitted by the side surface of the LED chip 107 and light emitted by the top surface of the LED chip 107.

The molding phosphor 115 may cover the bottom surface of the light-emitting structure 108. That is, when a boundary between the light-emitting structure 108 and the phosphor film 105 is defined as a reference level, a level H2 of a bottom surface 115B of the molding phosphor 115 may be lower than a level H1 of a bottom surface 108B of the light-emitting structure 108. Thus, even if light is emitted through the side surface and bottom surface of the LED chip 107, the light may be converted by the molding phosphor 115 and emitted. Thus, the molding phosphor 115 may reduce a color deviation of light in the LED package 100.

In example embodiments, the level H2 of the bottom surface 115B of the molding phosphor 115 may be between the level H1 of the bottom surface 108B of the light-emitting structure 108 and the level H2 of the bottom surface 109B of the electrode 109.

The molding phosphor 115 may be excited by light emitted by the LED chip 107 and convert at least part of the light into light having a different wavelength. For example, when the LED chip 107 generates blue light, the blue light generated by the LED chip 107 may be wavelength-converted into white light by a wavelength conversion material contained in the phosphor film 105.

The molding phosphor 115 may include the same phosphor material as the phosphor film 105. That is, the molding phosphor 115 may include a resin containing a wavelength conversion material. For example, the wavelength conversion material may be a phosphor material, and the resin may be a silicone resin, an epoxy resin, or a resin mixture thereof. The molding phosphor 115 may have electrical insulating characteristics. When the wavelength conversion material included in the molding phosphor 115 includes at least two materials having different wavelengths, the molding phosphor 115 may include phosphor materials at the same content ratio as the phosphor materials included in the phosphor film 105. Examples of materials included in the molding phosphor 115 will be described in detail with reference to FIGS. 8 to 10.

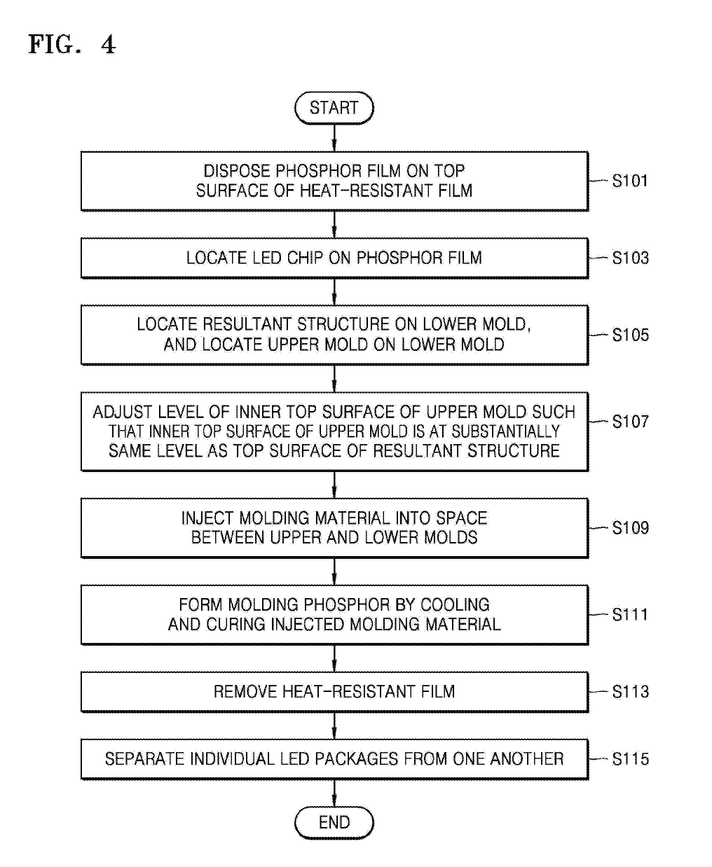

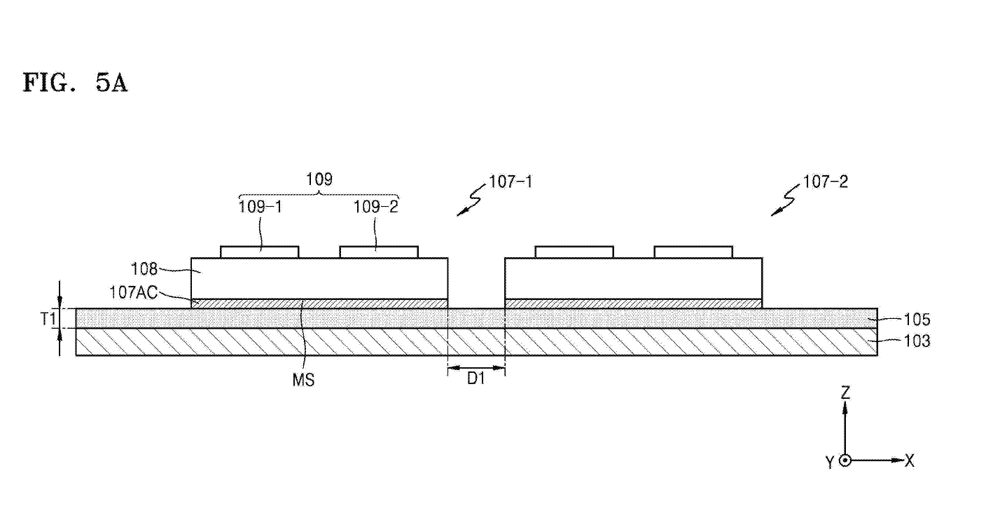

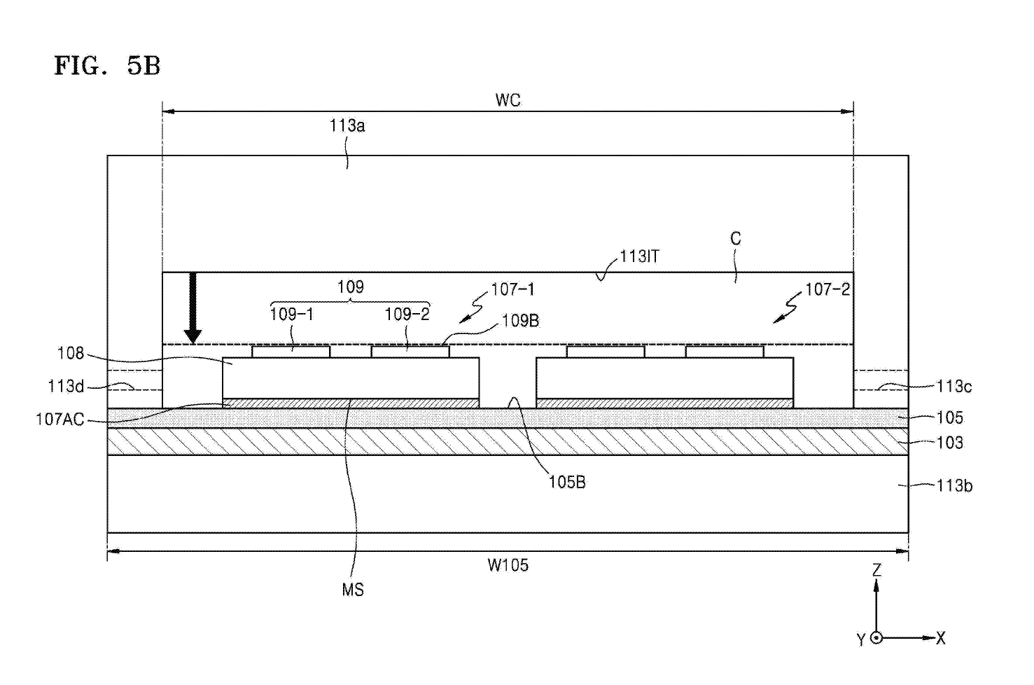

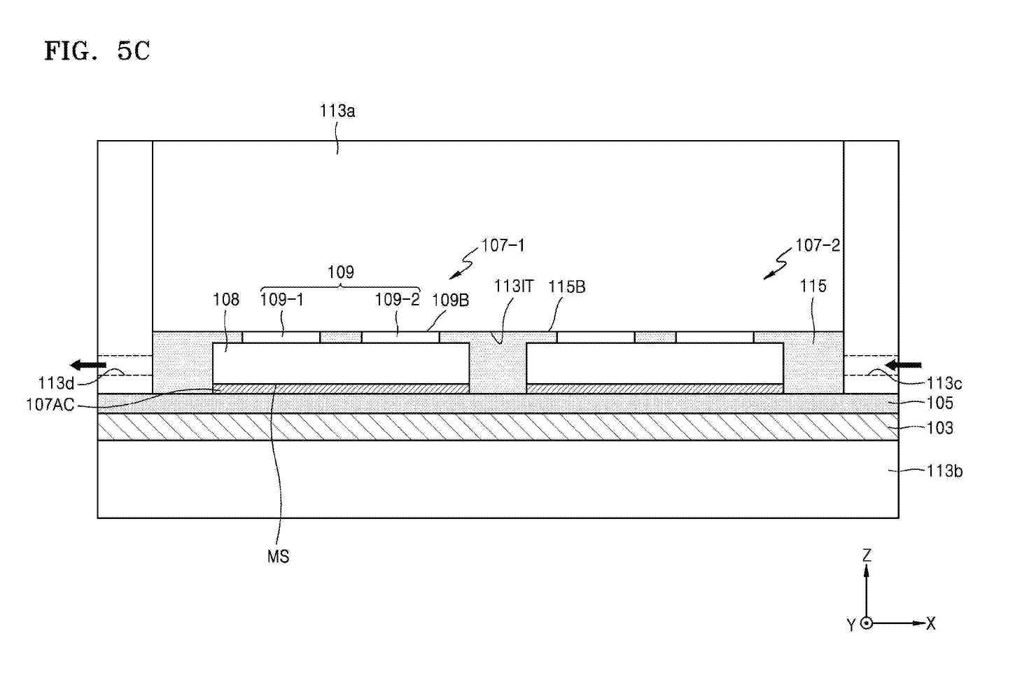

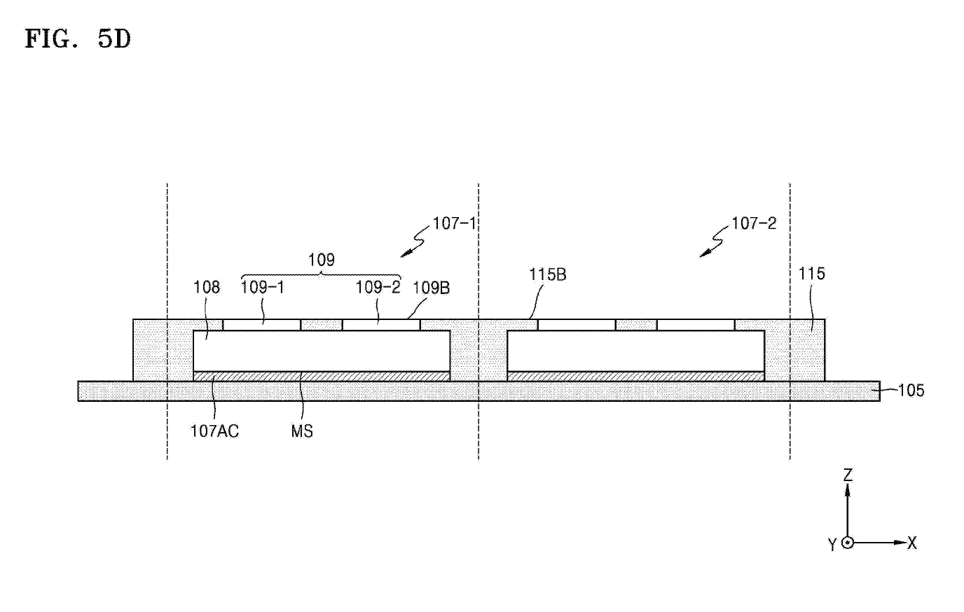

The molding phosphor 115 may be a curing resin or a semi-curing resin. The curing resin may be a resin that remains flowable before a curing process, and may be cured with application of energy, such as heat or UV light. The term “semi-curing” refers to a state in which a resin structure is not completely cured but cured so as to be easily handled and processed. The semi-cured resin structure may be bonded under pressure at an appropriate temperature to a side surface of the LED chip 107 and a bottom surface of the phosphor film 105. That is, the molding phosphor 115 may be formed by placing the LED chip 107 in a lower mold and an upper mold, injecting a phosphor material into the lower mold and the upper mold, and curing the phosphor material. A method of forming the molding phosphor 115 will be described later with reference to FIGS. 4 to 5D.

Although the molding phosphor 115 is illustrated as covering the entire side surface of the electrode 109, inventive concepts are not limited thereto. In example embodiments, the molding phosphor 115 may cover only a portion of the side surface of the electrode 109.

Although not shown, a lens may be further located on the phosphor film 105. The lens may have various structures capable of varying an orientation angle of light emitted by the phosphor film 105. That is, a top surface of the lens may have various shapes (e.g., a flat shape, a convex shape, or a concave shape) as desired. The lens may include a transmissive material, for example, a silicone resin.

In general, an LED package may be manufactured by mounting an LED chip on a lead frame substrate. In this case, since an additional substrate is adopted, the volume of the LED package may increase and the total manufacturing costs may increase. Thus, the demand for downscaling the LED package may increase.

However, it is difficult to form phosphor on a downscaled LED package to a uniform thickness to emit light of uniform color. When light generated by an LED chip passes phosphor having a non-uniform thickness, the light may be converted into light in different colors according to positions so that color deviation of emitted light may increase. Also, when light is emitted through a side surface and a bottom surface of the LED chip, on which phosphor is not formed, color deviation of light may increase due to light leakage (or emission of light that is not color-converted).

In the LED package 100 according to example embodiments of inventive concepts, since the phosphor film 105 having a uniform thickness is adhered to the top surface of the LED chip 107, phosphor may not have a non-uniform thickness without performing a process of adjusting a thickness of the phosphor film 105. Thus, light passing through the phosphor film 105 may be converted into light of uniform color. That is, color deviation of light emitted by the LED package 100 may be reduced, thus improving optical quality.

In addition, the molding phosphor 115 may be on the side surface and bottom surface of the light-emitting structure 108, on which the phosphor film 105 is not formed, among the exposed surfaces of the light-emitting structure 108 from which light is generated. In this case, since the molding phosphor 115 is formed by using a molding process, the molding phosphor 115 may cover all the exposed surfaces of the light-emitting structure 108 without being affected by the rough portion formed on the light-emitting structure 108 (e.g., the structure of the electrode 109). Thus, in the LED package 100, since light generated by the LED chip 107 is not emitted without color conversion, light leakage may be reduced. Rather, the light generated by the LED package 100 may be completely color-converted and emitted, thereby enhancing optical efficiency.

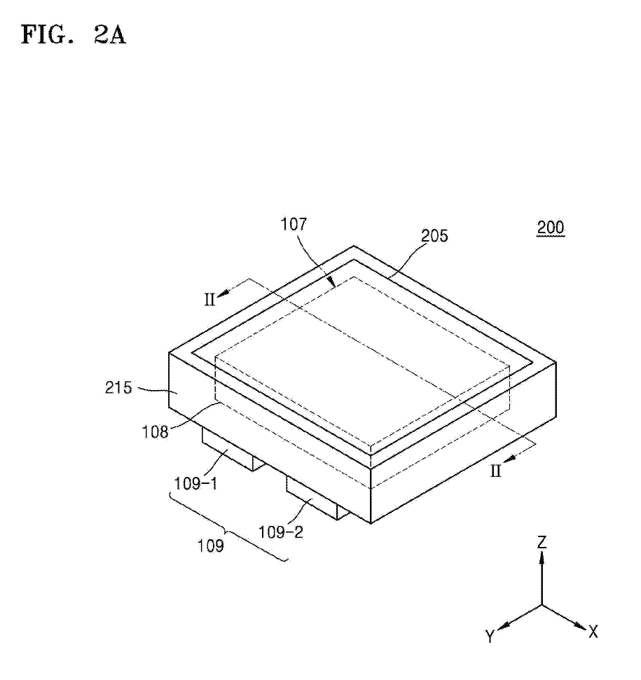

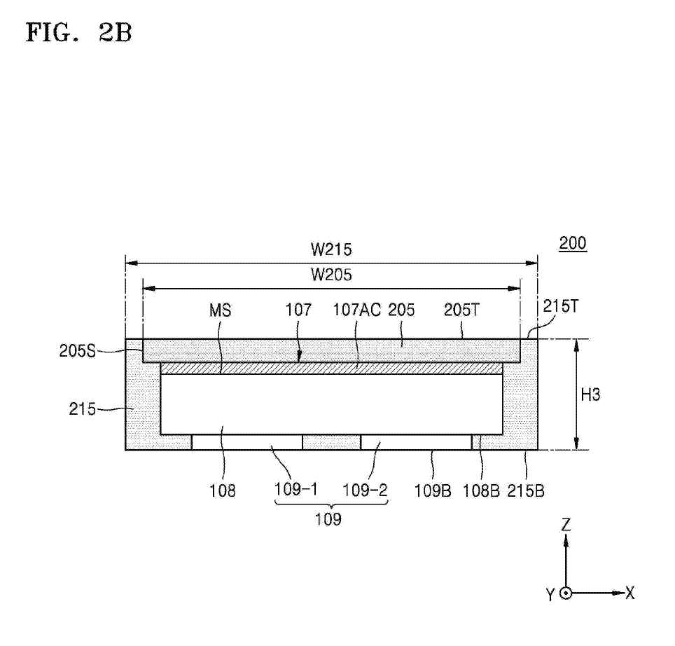

FIG. 2A is a perspective view of an LED package 200 according to example embodiments. FIG. 2B is a cross-sectional view taken along a line II-II of FIG. 2A. The LED package 200 may be similar to the LED package 100 of FIGS. 1A and 1B except for an area of a phosphor film 205 and a shape of a molding phosphor 215. The same reference numerals are used to denote the same elements as in FIGS. 1A and 1B, and repeated descriptions thereof are omitted.

Referring to FIGS. 2A and 2B, the LED package 200 may include an LED chip 107, the phosphor film 205 adhered to a top surface of the LED chip 107, and the molding phosphor 215 covering a side surface of the LED chip 107 and a side surface 205S of the phosphor film 205. Since the molding phosphor 215 covers the side surface 205S of the phosphor film 205, an outermost width W215 of the molding phosphor 215 may be greater than a width W205 of the phosphor film 205.

When a level of a bottom surface of an electrode 109 in the LED chip 107 is defined as a reference level, a level H3 of a top surface 215T of the molding phosphor 215 may be equal to a level H3 of a top surface 205T of the phosphor film 205. Also, the molding phosphor 215 may cover a bottom surface 108B of a light-emitting structure 108 in the LED chip 107. That is, the LED package 200 may have such a shape surrounded with the molding phosphor 215.

Thus, even if light is emitted through a side surface and a bottom surface of the LED chip 107, the light may be color-converted and emitted in the same way as by the phosphor film 205. Light generated by the LED chip 107 may be converted into white light by the phosphor film 205 and the molding phosphor 215 and omnidirectionally emitted.

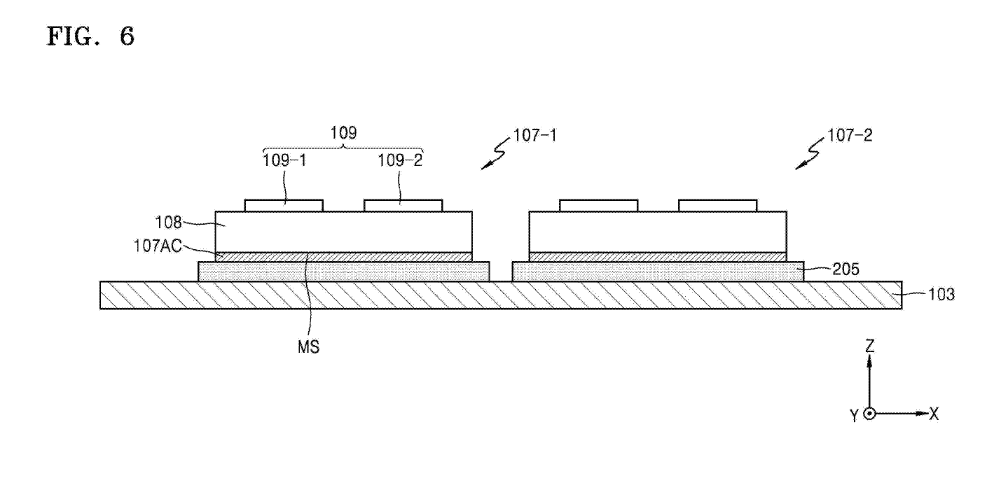

The phosphor film 205 of the LED package 200 may be formed by adhering a singulated film to the LED chip 107. The formation of the phosphor film 205 will be described later with reference to FIG. 6.

The LED package 200 including the phosphor film 205 may reduce color deviation of light emitted through the top surface of the LED chip 107. Simultaneously, the molding phosphor 215 may be formed by molding a region other than the top surface of the LED chip 107 with a flowable phosphor material. Thus, light leakage may be limited (and/or prevented) and optical efficiency may be improved.

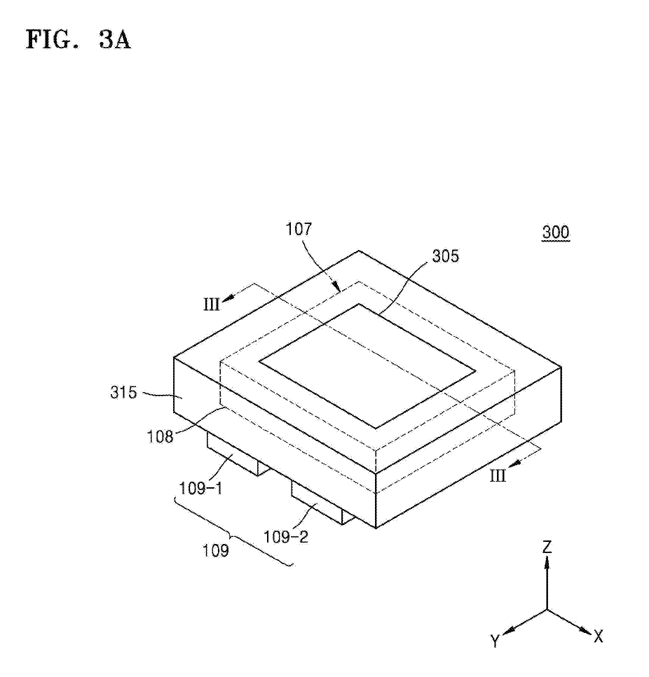

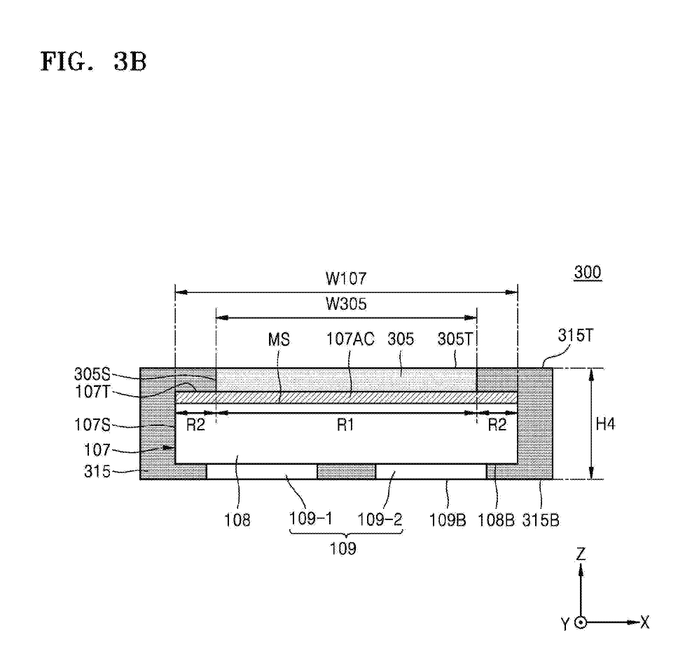

FIG. 3A is a perspective view of an LED package 300 according to example embodiments. FIG. 3B is a cross-sectional view taken along a line III-III of FIG. 3A. The LED package 300 may be similar to the LED package 100 of FIGS. 1A and 1B except for an area of a phosphor film 305, a shape of a molding body 315, and a material included in the molding body 315.

Referring to FIGS. 3A and 3B, the LED package 300 may include an LED chip 107, the phosphor film 305 having an area smaller than an area of the LED chip 107 and adhered to a top surface 107T of the LED chip 107, and the molding body 315 covering a side surface 305S of the phosphor film 305 and the top surface 107T and a side surface 107S of the LED chip 107.

A width W305 of the phosphor film 305 may be less than a width W107 of the LED chip 107. Thus, the top surface 107T of the LED chip 107 may be divided into a first region R1, to which the phosphor film 305 is adhered, and a second region R2 other than the first region R1. That is, the second region R2 may not overlap the phosphor film 305. The second region R2 of the top surface 107T of the LED chip 107 may be covered with the molding body 315.

The molding body 315 may cover the entire side surface 305S of the phosphor film 305, while the molding body 315 may cover the top surface 107T and the side surface 107S of the LED chip 107. Also, when a level of a bottom surface of an electrode 109 in the LED chip 107 is defined as a reference level, a level H4 of a top surface 315T of the molding body 315 may be equal to a level H4 of a top surface 305T of the phosphor film 305. Also, the molding body 315 may cover a bottom surface 108B of a light-emitting structure 108 in the LED chip 107. Thus, the LED package 300 may have a shape surrounded with the molding body 315.

The molding body 315 may include a non-transmissive material. Also, the molding body 315 may include a non-transmissive high-reflective material, for example, a resin including high-reflective powder. The high-reflective powder in the molding body 315 may limit (and/or prevent) light generated by the LED chip 107 from being absorbed into the molding body 315 or lost in a side surface of the LED chip 107 to increase luminance.

In example embodiments, the high-reflective powder may include high-reflective metal powder, for example, Al powder or Ag powder. The high-reflective metal powder may be appropriately included in the molding body 315 in such a range as to maintain the molding body 315 as an insulating material. Also, the high-reflective powder may include ceramic powder, for example, at least one selected from the group consisting of TiO₂, Al₂O₃, Nb₂O₅, Al₂O₃, and ZnO.

In example embodiments, the molding body 315 may include a white epoxy resin or silicone resin having a high reflectance.

The first region R1, to which the phosphor film 305 is adhered, from among the top surface 107T of the LED chip 107, may be an emission window region, and light generated by the LED chip 107 may be color-converted and emitted to the emission window region. In contrast, the second region R2, which is covered with the molding body 315 including the non-transmissive material, from among the top surface 107T of the LED chip 107 may not emit light. That is, an emission window region of the LED package 300 may be controlled by selecting an area of the phosphor film 305.

From among light generated by the LED chip 107, light emitted to the second region R2 of the LED chip 107 and the side surface 107S and the bottom surface 107B of the LED chip 107 may be reflected by the molding body 315 and emitted through the first region R1. That is, the LED package 300 including the phosphor film 305 may reduce color deviation of light emitted through the top surface of the LED chip 107 and simultaneously, adjust a range of an emission window as desired. Also, a region other than the emission window may form the molding body 315 by molding a flowable high-reflective material, so that light leakage may be limited (and/or prevented) and optical efficiency may be improved.

FIG. 4 is a flowchart of process operations of methods 100, 200, and 300 of manufacturing the LED packages of FIGS. 1A to 3B. FIGS. 5A to 5D are cross-sectional views of process operations of a method of manufacturing the LED package 100 shown in FIGS. 1A and 1B.

Referring to FIGS. 4 and 5A, to begin with, the method of manufacturing the LED package 100 may include adhering a phosphor film 105 to a heat-resistant film 103 (S101) and locating a plurality of LED chips (e.g., 107-1 and 107-2), on the phosphor film 105 a desired (and/or alternatively predetermined) distance D1 apart from one another (S103).

The heat-resistant film 103 may include a material of which physical properties are not changed while a material included in the molding phosphor 115 described above with reference to FIGS. 1A to 1D is processed at a high temperature. The heat-resistant film 103 may serve to protect the phosphor film 105 from being in direct contact with a mold during an operation (refer to S109 in FIG. 5C) of injecting a molding material by applying pressure at a high temperature.

The phosphor film 105 may have such a wide area as to cover the plurality of LED chips 107-1 and 107-2. In this case, the phosphor film 105 may have a uniform thickness over the entire surface thereof. The phosphor film 105 may be formed by using an additional process before or during a process of manufacturing the LED package. The formation of the phosphor film 105 may include mixing a phosphor material with a resin and molding the mixture by applying pressure, but inventive concepts are not limited thereto.

The heat-resistant film 103 and the phosphor film 105 may have a wider area than a cavity C of a mold (or an upper mold 113a and a lower mold 113b) that is adopted in operations (refer to S109 and S111 in FIG. 5B) of injecting and curing the molding material.

The LED chips 107-1 and 107-2 may be separated into single chips on a wafer level. Each of the LED chips 107-1 and 107-2 may be located such that a main surface MS of a light-emitting structure 108 opposite to a surface of the light-emitting structure 108 on which an electrode 109 is formed may face the phosphor film 105.

The LED chips 107-1 and 107-2 may be located a desired (and/or alternatively predetermined) distance D1 apart from one another on the phosphor film 105. In this case, the distance D1 may be equal to or greater than twice a thickness T1 of the phosphor film 105. That is, the molding phosphor 115 filled between adjacent ones of the plurality of LED chips 107-1 and 107-2 in the operations (refer to S109 and S111 in FIG. 5C) may be halved due to operation S115 of singulating individual LED packages of FIG. 5D. Accordingly, the distance D1 may be adjusted not to increase a difference between a thickness T2 of the molding phosphor 115 included in each of the LED packages 100 and the thickness T1 of the phosphor film 105.

Referring to FIGS. 4 and 5B, the resultant structure of FIG. 5A may be located in the lower mold 113b, and the upper mold 113a may be located on the lower mold 113b (S105). The LED chip 107 may be located in the cavity C defined by the upper mold 113a and the lower mold 113b. In this case, a width W105 of the heat-resistant film 103 and the phosphor film 105 may be greater than a width WC of the cavity C. Thus, the heat-resistant film 103 and the phosphor film 105 may be placed between the upper mold 113a and the lower mold 113b.

The upper mold 113a may include an injection route 113c configured to inject a material into the cavity C and a discharge route 113d configured to discharge the remaining material after the cavity C is filled with the material.

Thereafter, a level of an inner top surface 113IT of the upper mold 113a may be adjusted such that the inner top surface 113IT of the upper mold 113a is in contact with a top surface of the electrode 109 of the LED chip 107 (S107).

Referring to FIGS. 4 and 5C, a molding material may be injected into the cavity C between the upper and lower molds 113a and 113b (S109).

Specifically, a molding material prepared by mixing a phosphor material with molding compound powder may be put into a port located in the upper and lower molds 113a and 113b. Thereafter, by applying pressure to the molding material contained in the port while heating the molding material, a fused molding material may be injected under pressure into the cavity C through the injection route 113c. The molding material may be injected under pressure until the cavity C is completely filled with the molding material. Thus, the molding material may define a top surface of the phosphor film 105, a side surface of the LED chip 107, and the electrode 109 and cover a bottom surface of the LED chip 107.

Subsequently, the molding phosphor 115 may be formed by cooling and curing the injected molding material (S111).

In this case, the molding phosphor 115 may include at least two phosphor layers having different emission wavelengths to control efficiency of an LED package. Also, the molding phosphor 115 may include a DBR (or an omnidirectional reflector (ODR)) layer provided between the respective phosphor layers in order to minimize re-absorption of wavelength and interference between the LED chip 107 and the at least two phosphor layers.

Also, quantum dots (QDs) may be located on the LED chip 107 in the same manner as the molding phosphor 115. Alternatively, the QDs may be between glasses or between transparent polymer material layers and perform a light conversion operation.

An additional transmissive material layer may be located on the LED chip 107 to protect the LED chip 107 from the outside or improve light extraction efficiency of the LED chip 107. The transmissive material layer may be a transparent organic material, such as an epoxy, silicone, a hybrid of an epoxy and silicone, and may be cured by heating or irradiation with light, or by allowing for the transmissive material layer to set over a desired (and/or alternatively predetermined) period of time. Polydimethylsiloxane (PDMS) may be categorized as a methyl-based silicone, while polymethylphenyl siloxane may be categorized as a phenyl-based silicone. The methyl-based silicone may differ from the phenyl-based silicone in terms of refractive index, moisture permeability, light transmittance, light-resistant stability, and heat-resistant stability. Also, the silicone may be cured at a different rate according to a crosslinking agent and a catalyst and affect dispersion of phosphor.

Light extraction efficiency may depend on a refractive index of the transmissive material layer. At least two silicones having different refractive indices may be sequentially stacked to minimize a difference in refractive index between a medium located at an outermost portion of a chip from which blue light is emitted and a medium from which light emitted into the air. In general, the methyl-based silicone may have the highest heat-resistant stability, and the phenyl-based silicone, the hybrid, and the epoxy may vary at a low rate with a rise in temperature in an orderly fashion. Silicones may be classified into a gel type, an elastomer type, and a resin type according to hardness.

A lens may be further provided on the LED chip 107 to radially guide light irradiated by a light source. In this case, a previously shaped lens may be attached onto the LED chip 107. Alternatively, a flowable organic solvent may be injected into a mold on which the LED chip 107 is mounted, and solidified to form the lens. The lens may be directly attached to a filler formed on the LED chip 107 or spaced apart from the filler by adhering an outer portion of the LED chip 107 to an outer portion of the lens. Meanwhile, the flowable organic solvent may be injected into the mold by using an injection molding process, a transfer molding process, or a compression molding process. Light distribution characteristics may be affected by a shape of the lens (e.g., a concave shape, a convex shape, a rough shape, a conic shape, or a geometric structure). The shape of the lens may be modified to meet the needs for efficiency and light distribution characteristics.

Referring to FIGS. 4 and 5D, the heat-resistant film 103 may be removed from the resultant structure of FIG. 5C (S113). Subsequently, discrete LED packages may be separated into one another (S115), thereby completing the manufacture of the LED package 100 shown in FIGS. 1A and 1B.

FIG. 6 is a cross-sectional view of process operations of a method of manufacturing the LED package 200 shown in FIGS. 2A and 2B. The method of manufacturing the LED package 200 may be similar to the method of manufacturing the LED package 100 shown in FIGS. 4 and 5A to 5D except that phosphor films 205 adhered to a top surface of a heat-resistant film 103 are previously separated from one another and cover only individual LED chips 107, respectively. Accordingly, the method shown in FIGS. 4 and 5A to 5D will be referred to by replacing the phosphor film 105 shown in FIGS. 5B to 5D with the phosphor film 205 shown in FIG. 6.

Referring to FIGS. 4 and 6, the method of manufacturing the LED package 200 may include adhering a plurality of phosphor films 205, each of which covers a plurality of LED chips (e.g., 107-1 and 107-2), to the heat-resistant film 103 such that the plurality of phosphor films 205 are spaced apart from one another (S101). In this case, the top surface of the heat-resistant film 103 may be exposed in a space between the plurality of phosphor films 205. Thereafter, the plurality of LED chips 107-1 and 107-2 may be located on the plurality of phosphor films 205, respectively (S103).

Referring to FIGS. 4 and 5B, the resultant structure of FIG. 6 may be located on the lower mold 113b, and the upper mold 113a may be located on the lower mold 113b (S105). In this case, a width W105 of the heat-resistant film 103 may be greater than a width WC of a cavity C. Thus, the heat-resistant film 103 may be placed between the upper mold 113a and the lower mold 113b.

Thereafter, a level of an inner top surface 113IT of the upper mold 113a may be adjusted such that the inner top surface 113IT of the upper mold 113a is in contact with a top surface of an electrode 109 of the LED chip 107 (S107).

Referring to FIGS. 4 and 5C, a molding material may be injected into the cavity C between the upper and lower molds 113a and 113b (S109). The molding material may cover the top surface of the heat-resistant film 103 exposed between the separated phosphor films 205 and fill spaces between the separated phosphor films 205.

Thereafter, a molding phosphor 215 may be formed by cooling and curing the injected molding material (S111).

Referring to FIGS. 4 and 5D, the heat-resistant film 103 may be removed from the resultant structures of FIG. 5C (S113). Thereafter, individual LED packages may be separated into one another (S115), thereby completing the manufacture of the LED package 200 of FIGS. 2A and 2B.

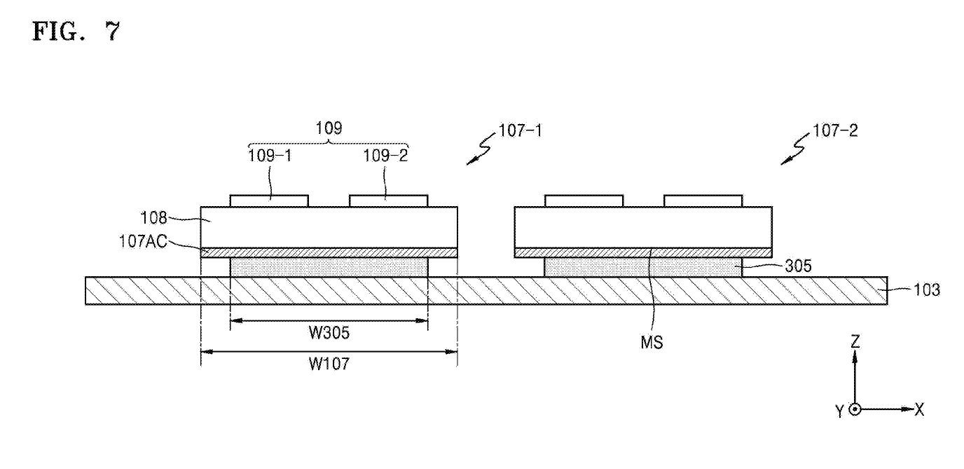

FIG. 7 is a cross-sectional view of process operations of a method of manufacturing the LED package 300 shown in FIGS. 3A and 3B. The method of manufacturing the LED package 300 may be similar to the method of manufacturing the LED package 100 shown in FIGS. 4 and 5A to 5D except that phosphor films 305 adhered to a top surface of a heat-resistant film 103 are previously separated from one another and cover only individual LED chips 107, respectively, and a width W305 of each of the phosphor films 305 is less than a width W107 of each of the LED chips 107. Accordingly, the method shown in FIGS. 4 and 5A to 5D will be referred to by replacing the phosphor film 105 shown in FIGS. 5B to 5D with the phosphor film 305 shown in FIG. 7.

Referring to FIGS. 4 and 7, to begin with, the method of manufacturing the LED package 300 may include adhering a plurality of phosphor films 305 to a top surface of the heat-resistant film 103 such that a plurality of LED chips (e.g., 107-1 and 107-2) are covered with a plurality of phosphor films 305, respectively (S101). In this case, a width W305 of an individual phosphor film 305 may be less than a width W107 of the LED chip 107. The top surface of the heat-resistant film 103 may be exposed in spaces between the plurality of phosphor films 305.

Subsequently, the plurality of LED chips 107-1 and 107-2 may be located on the plurality of phosphor films 305, respectively (S103).

Referring to FIGS. 4 and 5B, the resultant structure of FIG. 7 may be located in a lower mold 113b, and an upper mold 113a may be located on the lower mold 113b (S105). In this case, a width W105 of the heat-resistant film 103 may be greater than a width WC of a cavity C. Thus, the heat-resistant film 103 may be placed between the upper mold 113a and the lower mold 113b.

Thereafter, a level of an inner top surface 113IT of the upper mold 113a may be adjusted such that the inner top surface 113IT of the upper mold 113a is in contact with a top surface of an electrode 109 of the LED chip 107 (S107).

Referring to FIGS. 4 and 5C, a molding material may be injected into the cavity C between the upper and lower molds 113a and 113b (S109). The molding material may fill a space defined by the top surface of the heat-resistant film 103, which is exposed between the plurality of phosphor films 305, between the plurality of phosphor films 305 formed apart from one another.

The molding material may include a non-transmissive material or a material containing high-reflective powder. Detailed descriptions of the molding material are the same as described above with reference to FIGS. 3A and 3B.

Thereafter, a molding phosphor 315 may be formed by cooling and curing the injected molding material (S111).

Referring to FIGS. 4 and 5D, the heat-resistant film 103 may be removed from the resultant structure of FIG. 5C (S113). Thereafter, individual LED packages may be separated from one another (S115), thereby completing the manufacture of the LED package 300 shown in FIGS. 3A and 3B.

FIG. 8 is a graph showing a Planckian spectrum. Each of the LED packages 100 to 300 described with reference to FIGS. 1A to 3B may emit blue light, green light, red light, or UV light according to the kind of a compound semiconductor included in the LED chips 107 of the LED packages 100 to 300.

Color of light emitted by the LED packages 100 to 300 may be determined by controlling the wavelength of light generated by the LED chip 107 and kinds and combination ratios of the phosphor films 105, 205, and 305 and the molding phosphor 115, 215, and 315. That is, a color temperature and color rendering index (CRI) of light emitted by the LED packages 100 to 300 may depend on designer's selections.

For example, when the LED chip 107 emits blue light or UV light, the phosphor films 105, 205, and 305 and the molding phosphors 115, 215, and 315 may include at least one of yellow, green, red, and blue phosphors, and the LED packages 100, 200, and 300 may emit white light having various color temperatures according to a combination ratio of the phosphors. Alternatively, when the LED chip 107 emits blue light and the phosphor films 105, 205, and 305 and the molding phosphors 115, 215, and 315 include green or red phosphors, the LED packages 100, 200, and 300 may emit green or red light. Alternatively, an LED package may include at least one of LED chips configured to emit purple light, blue light, green light, red light, or IR light.

Furthermore, a color temperature and CRI of white light may be controlled by combining an LED package configured to emit white light with an LED package configured to emit red light.

A CRI of the LED packages 100 to 300 may be controlled to be 100 (e.g., solar light). Also, the LED packages 100 to 300 may emit various types of white light having a color temperature ranging from 1500 K to 20000 K. When necessary, color of illumination light may be adjusted to an ambient atmosphere or mood by generating visible light (e.g., purple light, blue light, green light, red light, and orange light) or infrared (IR) light. Also, the LED packages 100 to 300 may generate light having a special wavelength to facilitate growth of plants.

Referring to FIG. 8, white light generated by a combination of the blue LED chip 107 with yellow, green, red phosphor and/or green and red LED chips 107 may have at least two peak wavelengths. Coordinates (x, y) of the white light in a CIE 1931 coordinate system may be located on a segment connecting (0.4476, 0.4074), (0.3484, 0.3516), (0.3101, 0.3162), (0.3128, 0.3292), and (0.3333, 0.3333) or located in a region surrounded with the segment and a blackbody radiator spectrum. In FIG. 8, since the white light around point E (0.3333, 0.3333) disposed under the black-body radiator spectrum is relatively weak in the light of the yellow-based component, it may be used as an illumination light source in a region in which a user may have a more vivid or fresh feeling than naked eyes. Therefore, an illumination product using the white light around point E (0.3333, 0.3333) disposed under the black-body radiator spectrum may be suitable as lighting for shopping malls that sell groceries and clothes.

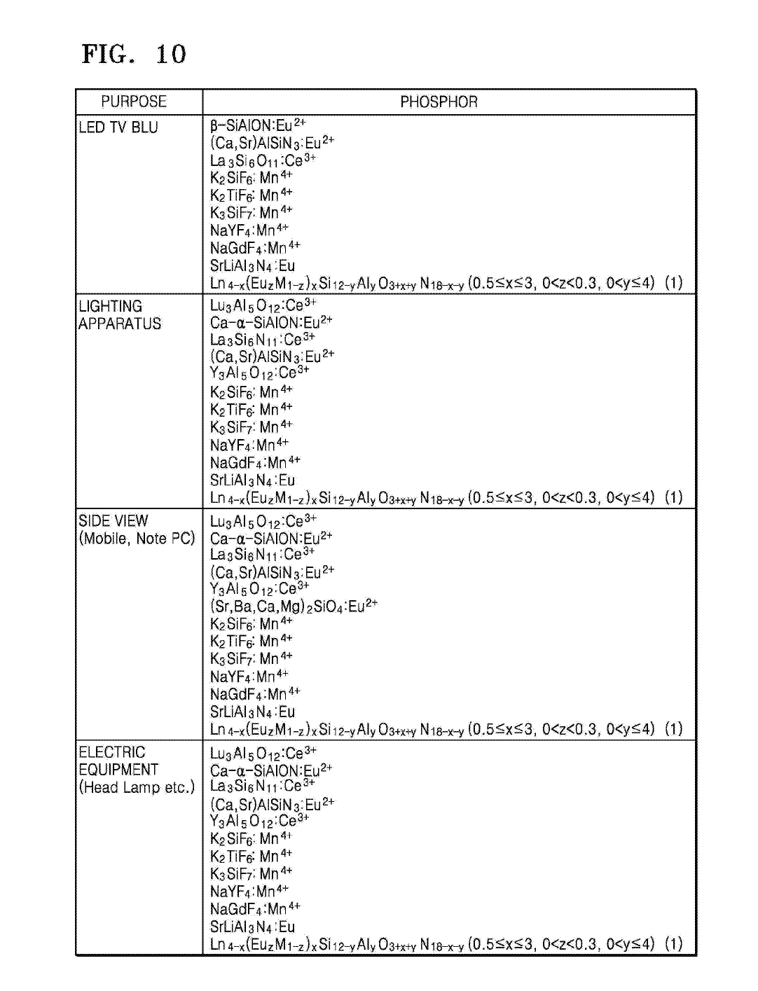

In example embodiments, the phosphor films 105, 205, and 305 and the molding phosphors 115, 215, and 315 of the LED packages 100 to 300 may have empirical formulas and colors as described with reference to FIG. 10.

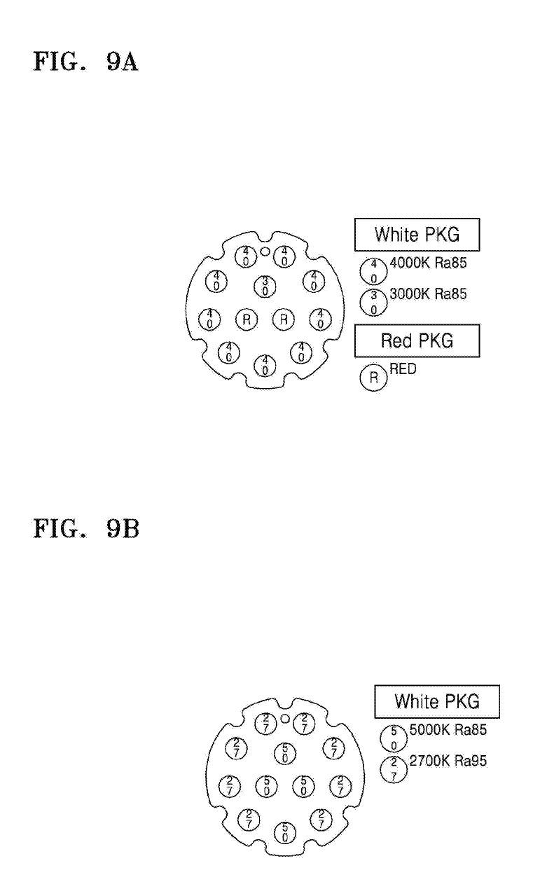

FIGS. 9A and 9B show white light-emitting package modules including the LED packages 100, 200, and 300 manufactured according to example embodiments.

Referring to FIG. 9A, a white light-emitting package module may be manufactured by combining white LED packages having color temperatures of about 4,000 K and about 3,000 K with a red LED package. The white light-emitting package module may adjust a color temperature in the range of about 3,000 K to about 4,000 K and provide white light having a CRI Ra of about 85 to about 99.

Referring to FIG. 9B, a white light-emitting package module may be manufactured by combining a white LED package having a color temperature of about 2,700 K with a white LED package having a color temperature of about 5,000 K. The white light-emitting package module may adjust a color temperature in the range of about 2,700 K to about 5,000 K and provide white light having a CRI Ra of about 85 to about 99. The number of LED packages for each color temperature may be changed according to a basic color temperature setting value. For example, in a lighting apparatus, of which a basic color temperature setting value is around a color temperature of about 4,000 K, the number of packages corresponding to a color temperature of about 4,000 K may be larger than the number of packages corresponding to a color temperature of about 3,000 K or the number of red LED packages.

The phosphor may have the following empirical formulas and colors.

Oxide-based p: yellow and green color (Y, Lu, Se, La, Gd, Sm, Tb)₃(Ga, Al)₅O₁₂:Ce and blue color BaMgAl₁₀O₁₇:Eu, 3Sr₃(PO₄)₂—CaCl:Eu

Silicate-based: yellow and green color (Ba, Sr)₂SiO₄:Eu, yellow and orange color (Ba, Sr)₃SiO₅:Eu, (Ba,Sr)₃SiO₅:Ce

Nitride-based: green color β-SiAlON:Eu, yellow color (La, Gd, Lu, Y, Sc)₃Si₆N₁₁:Ce, orange color α-SiAlON:Eu, red color (Sr, Ca)AlSiN₃:Eu, (Sr, Ca)AlSi(ON)₃:Eu, (Sr, Ca)₂Si₅N₈:Eu, (Sr, Ca)₂Si₅(ON)₈:Eu, (Sr, Ba)SiAl₄N₇:Eu,

SrLiAl₃N₄:Eu,Ln₄₋ₓ(Eu_{z}M_{1-z})ₓSi_{12-y}Al_{y}O_{3+x+y}N_{18-x-y}(0.5≦x≦3,0<z<0.3,0<y≦4)Formula(1)

In Formula (1), Ln may be at least one element selected from the group consisting of Group Ma elements and rare-earth elements, and M may be at least one element selected from the group consisting of calcium (Ca), barium (Ba), strontium (Sr), and magnesium (Mg)

Sulfide-based: red color (Sr, Ca)S:Eu, (Y, Gd)₂O₂S:Eu, green color SrGa₂S₄:Eu

Fluoride-based: KSF-based red color K₂SiF₆:Mn₄⁺, K₂TiF₆:Mn₄⁺, NaYF₄:Mn₄⁺, NaGdF₄:Mn₄⁺, K₃SiF₇:Mn₄⁺

The composition of the phosphor needs to basically conform with stoichiometry, and the respective elements may be substituted by other elements included in the respective groups of the periodic table. For example, strontium (Sr) may be substituted by at least one selected from the group consisting of barium (Ba), calcium (Ca), and magnesium (Mg) of alkaline-earth group II, and Y may be substituted by at least one selected from the group consisting of terbium (Tb), lutetium (Lu), scandium (Sc), and gadolinium (Gd) of the lanthanum group. In addition, europium (Eu), which is an activator, may be substituted by at least one selected from the group consisting of cerium (Ce), terbium (Tb), praseodymium (Pr), erbium (Er), and ytterbium (Yb) according to a desired energy level. The activator may be applied solely or a sub-activator may be additionally applied for characteristic modification. Also, materials, such as QDs, may be used as materials capable of replacing the phosphors, and the phosphors and the QD may be used alone or in combination with one another.

A QD may have a structure including a core (about 3 nm to about 10 nm), such as CdSe or InP, a shell (about 0.5 nm to about 2 nm), such as ZnS and ZnSe, and a ligand for stabilizing the core and the shell, and may be embodied in various colors according to size.

A wavelength conversion material, such as phosphors and QDs, may be implemented as being contained in an encapsulant. However, the wavelength conversion material may be previously prepared in a film shape and be attached to a top surface of an LED chip. In this case, the top surface of the LED chip may be coated with the wavelength conversion material to a uniform thickness.

FIG. 10 shows examples of phosphors according to applications included in a white LED package using a blue LED chip (about 440 nm to about 460 nm).

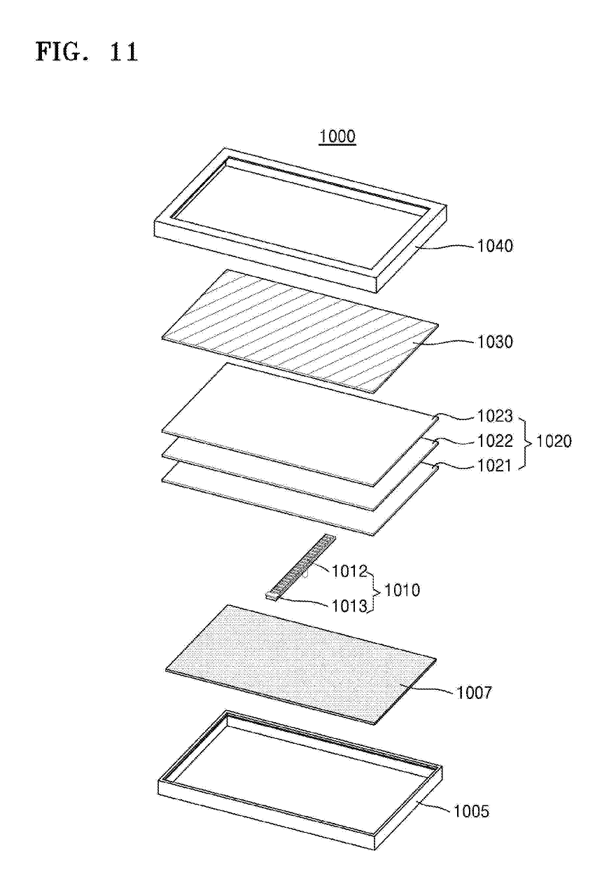

FIG. 11 is an exploded perspective view of a backlight (BL) assembly 1000 including an LED package according to example embodiments.

Referring to FIG. 11, a direct-light-type BL assembly 1000 may include a lower cover 1005, a reflection sheet 1007, a light-emitting module 1010, an optical sheet 1020, an LC panel 1030, and an upper cover 1040.

The light-emitting module 1010 may include an LED array 1012 including at least one LED and a circuit substrate and/or a controller (e.g., a rank storage unit and a driver IC) 1013. The light-emitting module 1010 may include at least one of the LED packages 100, 200, and 300 described with reference to FIGS. 1A to 3B.

The controller 1013 may store and control driving information of each LED included in the LED array 1012 and/or a driving program IC capable of controlling turning-on/off or brightness) of the LEDs separately or in groups. The LED array 1012 may receive emission power and driving information from an LED driver disposed outside the direct-light-type BL assembly 1000. The controller 1013 may sense the driving information from the LED driver and control current supplied to each of the LEDs of the LED array 1012 based on the sensed driving information.

The optical sheet 1020 may be provided on the light-emitting module 1010 and include a diffuser sheet 1021, a condensing sheet 1022, and a protection sheet 1023. That is, the diffuser sheet 1021 configured to diffuse light emitted by the light-emitting module 1010, the condensing sheet 1022 configured to condense the light diffused by the diffuser sheet 1021 and increase luminance, and the protection sheet 1023 configured to protect the condensing sheet 1012 and ensure a view angle may be sequentially prepared on the light-emitting module 1010. The upper cover 1040 may enclose an edge of the optical sheet 1020 and be assembled with the lower cover 1005. The LC panel 1030 may be further provided between the optical sheet 1020 and the upper cover 1040.

The LC panel 1030 may include a pair of a first substrate (not shown) and a second substrate (not shown), which may be bonded to each other so that an LC layer may be between the first and second substrates. A plurality of gate lines may intersect a plurality of data lines to define pixel regions on the first substrate. Thin-film transistors (TFTs) may be respectively provided at intersections between the pixel regions, and may correspond one-to-one to and be connected to pixel electrodes mounted on the respective pixel regions. The second substrate may include red (R), green (G), and blue (B) color filters respectively corresponding to the pixel regions and a black matrix covering edges of the respective color filters, the gate lines, the data lines, and the TFTs.

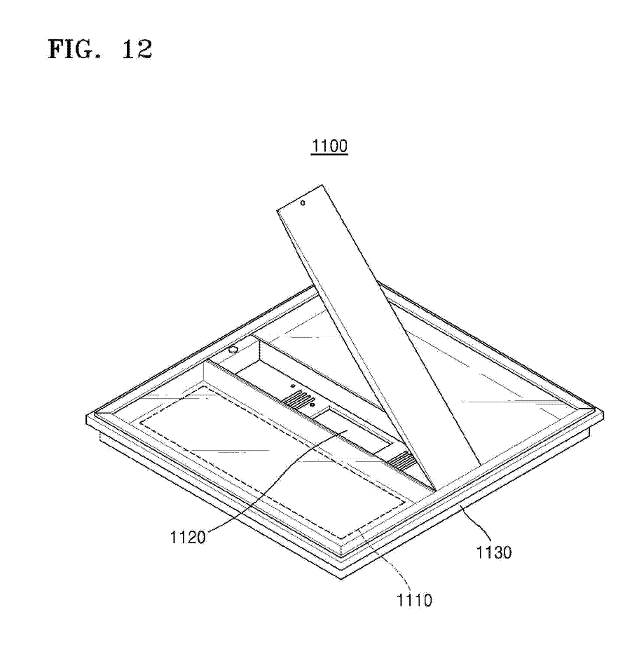

FIG. 12 is a schematic diagram of a flat-panel semiconductor light-emitting apparatus 1100 including an LED array unit and an LED module in which an LED according to example embodiments is arranged.

Referring to FIG. 12, the flat-panel semiconductor light-emitting apparatus 1100 may include a light source 1110, a power supply device 1120, and a housing 1130. The light source 1110 may include an LED array unit including at least one of the LED packages 100, 200, and 300 described with reference to FIGS. 1A to 3B.

The light source 1110 may include an LED array unit and have an overall plane shape.

The power supply device 1120 may be configured to supply power to the light source 1110.

The housing 1130 may include a containing space in which the light source 1110 and the power supply device 1120 are contained, and have a hexahedral shape having one open side surface, but inventive concepts are not limited thereto. The light source 1110 may be located to emit light toward the open side surface of the housing 1130.

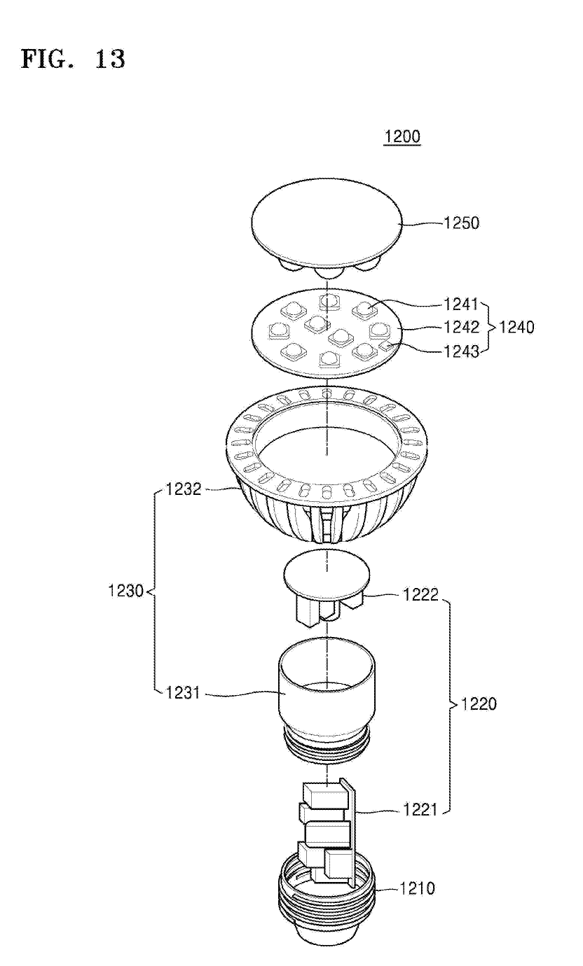

FIG. 13 is a schematic diagram of a bulb-type lamp, which is a semiconductor light-emitting apparatus 1200 including an LED array unit and an LED module in which an LED according to example embodiments is arranged.

Referring to FIG. 13, the semiconductor light-emitting apparatus 1200 may include a socket 1210, a power source unit 1220, a heat radiation unit 1230, a light source 1240, and an optical unit 1250. According to example embodiments, the light source 1240 may include an LED array unit including at least one of the LED packages 100, 200, and 300 described with reference to FIGS. 1A to 3B, according to example embodiments.

Power supplied to the lighting system 1200 may be applied through the socket 1210. The power source unit 1220 may be formed by assembling a first power source unit 1221 and a second power source unit 1222.

The heat radiation unit 1230 may include an internal radiation unit 1231 and an external radiation unit 1232. The internal radiation unit 1131 may be directly connected to the light source 1240 and/or the power source unit 1220 so that heat may be transmitted to the external radiation unit 1232. The optical unit 1250 may include an internal optical unit (not shown) and an external optical unit (not shown) and may be configured to uniformly disperse light emitted by the light source 1240.

The light source 1240 may receive power from the power source unit 1220 and emit light to the optical unit 1250. The light source 1240 may include an LED array unit including an LED according to one of the above-described embodiments. The light source 1240 may include at least one LED package 1241, a circuit substrate 1242, and a rank storage unit 1243, and the rank storage unit 1243 may store rank information of LED packages 1241.

A plurality of LED packages 1241 included in the light source 1240 may be of the same kind to generate light having the same wavelength. Alternatively, the plurality of LED packages 1241 included in the light source 1240 may be of different kinds to generate light having different wavelengths.

For example, the LED package 1241 may include a blue LED, a white LED manufactured by combining yellow, green, red, or orange phosphors, and at least one of violet, blue, green, red, or infrared (IR) LEDs so as to control a color temperature and a CRI of white light. Alternatively, when an LED chip emits blue light, an LED package including at least one of yellow, green, and red phosphors may be configured to emit white light having various color temperatures according to a combination ratio of the phosphors. Alternatively, an LED package in which a green or red phosphor is applied to the blue LED chip may be configured to emit green or red light. The LED package configured to emit white light may be combined with the LED package configured to emit green or red light so as to control a color temperature and CRI of white light. Also, the LED package 1241 may include at least one of LEDs configured to emit violet, blue, green, red, or IR light.

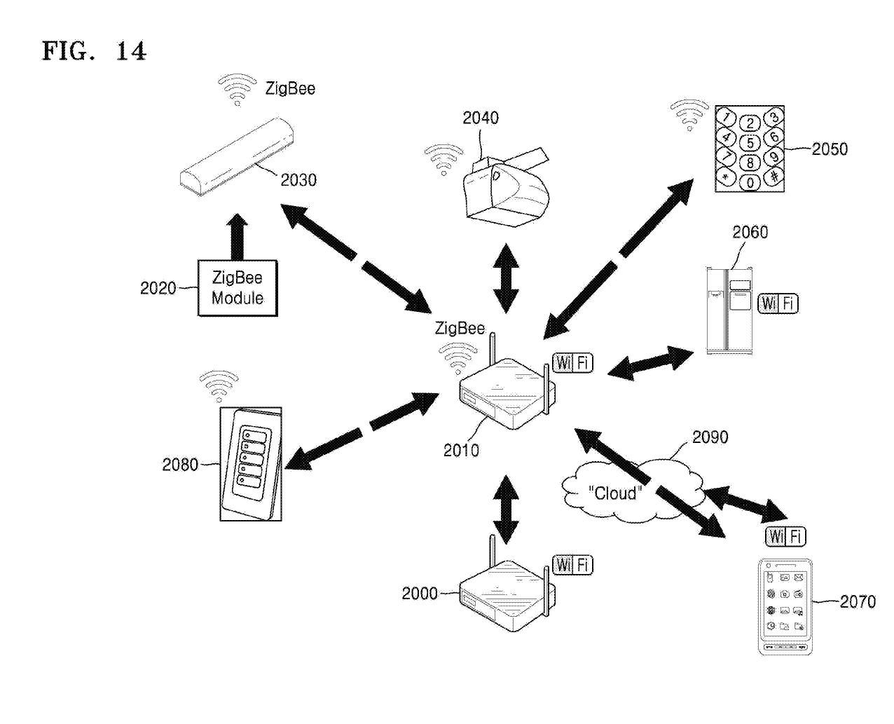

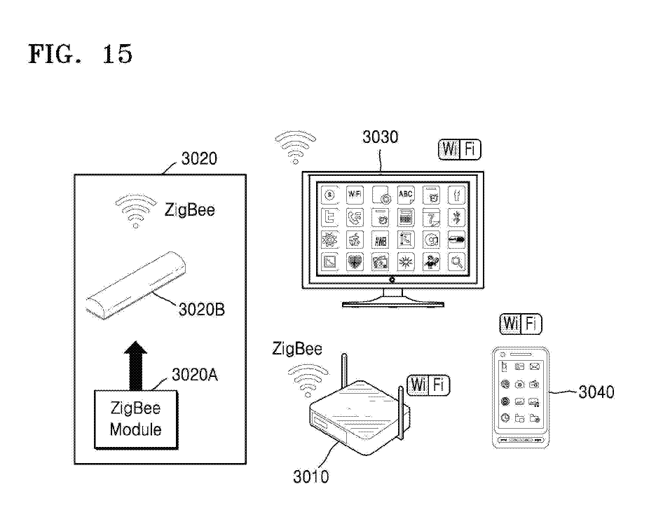

FIGS. 14 and 15 are diagrams of examples of applying a lighting system using an LED package according to example embodiments to a home network.

Referring to FIGS. 14 and 15, the home network may include a home wireless router 2000, a gateway hub 2010, a ZigBee module 2020, an LED lamp 2030, a garage door lock 2040, a wireless door lock 2050, a home application 2060, a cell phone 2070, a wall-mounted switch 2080, and a cloud network 2090.

The home network may automatically control the turn-on/off, color temperature, CRI, and/or brightness of the LED lamp 2030 using household wireless communications (e.g., ZigBee and WiFi) depending on operation states of a bedroom, a living room, a front door, a storage closet, and household appliances and ambient environments and statuses. For example, as shown in FIG. 15, the brightness, color temperature, and/or CRI of a lighting apparatus 3020B may be automatically controlled using a gateway 3010 and a ZigBee module 3020A depending on the type of a TV program viewed on a TV 3030 or the brightness of a screen of the TV 3030. When a program value of the TV program is a human drama, the lighting apparatus 3020B may lower a color temperature to 12,000K or less (e.g., 5,000K) and adjust a color sense according to a preset value, thus creating a cozy atmosphere. On the other hand, when a program value is a gag program, the home network may be configured such that the lighting apparatus 3020B may increase a color temperature to 5,000K or more according to a set value so as to be adjusted to bluish white light.

Furthermore, not only the on/off operations, brightness, color temperature, and/or CRI of the lighting apparatus 3020B but also electronic appliances, such as the TV 3030, refrigerators, and air conditioners, which are connected to the lighting apparatus 3020B, may be controlled using a household wireless protocol (e.g., ZigBee, WiFi, or LiFi) through a portable electronic device 3040 (e.g., smartphone, laptop computer, or a tablet computer). Here, the LiFi communication refers to a short-distance wireless communication protocol using visible light of a lighting apparatus. For example, an indoor lighting apparatus or electronic appliances may be controlled through a smartphone by using a method including realizing a lighting control application program of the smartphone, which indicates the graph (or a color coordinate system) of FIG. 8 and mapping a sensor connected to all lighting apparatuses installed at home in accordance with the color coordinate system by using a communication protocol (e.g., ZigBee, WiFi, LiFi, etc.), namely, indicating a position of the indoor lighting apparatus, a current setting value, and an on/off state value, changing a state value by selecting a lighting apparatus located in a specific position, and varying a state of the lighting apparatus according to the changed value.

The ZigBee module 2020 or 3020A may be unified with an optical sensor to form a module, or be unified with a light-emitting apparatus.

The visible light wireless communication technology is wireless communication technology that wirelessly transmits information by using light of a visible light wavelength the human may recognize with his/her eyes. The visible light wireless communication technology differs from the existing wired optical communication technology and infrared wireless communication in that the light of the visible light wavelength is used, and differs from the wired optical communication technology in that communication environment is a wireless environment. Contrary to the RF wireless communication technology, the visible light wireless communication technology may freely be used without regulation or permission in terms of frequency use. In addition, the visible light wireless communication technology has excellent physical security and has differentiation that enables a user to confirm a communication link with his/her eyes. Furthermore, the visible light wireless communication technology is convergence technology that is capable of simultaneously obtaining the unique purpose of a light source and a communication function.

In addition, an LED lighting apparatus may be used for an internal light source or an external light source for vehicles. The LED lighting apparatus may be used for an internal light source, such as an interior light, a reading light, or various lights for a gauge board for vehicles. Also, the LED lighting apparatus may be used for any external light source, such as a headlight, a brake light, a direction guide light, a fog light, a running light for vehicles.

An LED using a particular wavelength range may promote growth of plants, stabilize human feelings, or cure diseases. The LED may be used as a light source for robots or various mechanical apparatuses. Since the LED has low power consumption and a long lifetime, lighting apparatuses may be embodied by combining the LED with an eco-friendly renewable energy power system using solar cells or wind power.

It should be understood that example embodiments described herein should be considered in a descriptive sense only and not for purposes of limitation. Descriptions of features or aspects within each device or method according to example embodiments should typically be considered as available for other similar features or aspects in other devices or methods according to example embodiments. While some example embodiments have been particularly shown and described, it will be understood by one of ordinary skill in the art that variations in form and detail may be made therein without departing from the spirit and scope of the claims.

What is claimed is:

1. A light-emitting diode (LED) package comprising:
a LED chip;
a phosphor film on a top surface of the LED chip; and
a molding phosphor covering a side surface of the LED chip.

2. The LED package of claim 1, wherein
the phosphor film and the molding phosphor film are configured to convert light generated by the LED chip into white light, and
the LED chip is configured to emit light omnidirectionally.

3. The LED package of claim 1, wherein the phosphor film and the molding phosphor include identical phosphor materials.

4. The LED package of claim 3, wherein an interface exists between the molding phosphor and the phosphor film.

5. The LED package of claim 1, wherein a thickness of the molding phosphor located on the side surface of the LED chip is 1 to 2 times as large as a thickness of the phosphor film.

6. The LED package of claim 1, wherein
the LED chip includes a light-emitting structure and an electrode,
a bottom surface of the light-emitting structure is on the electrode, and
the molding phosphor extends towards a sidewall of the electrode.

7. The LED package of claim 6, wherein
a level of a bottom surface of the molding phosphor extends below the light emitting structure, and
a bottom surface of the light-emitting structure is on the molding phosphor.

8. The LED package of claim 1, wherein the phosphor film covers a top surface of a portion of the molding phosphor located at the side surface of the LED chip.

9. The LED package of claim 1, wherein the molding phosphor surrounds a side surface of the phosphor film.

10. The LED package of claim 1, wherein
an area of the phosphor film is less than an area of a top surface of the LED chip, and
the molding phosphor surrounds an outer side surface of the phosphor film and covers the top surface of the LED chip.

11. The LED package of claim 1, further comprising:
an adhesive layer between the LED chip and the phosphor film.

12. A light-emitting diode (LED) package comprising:
a LED chip;
a phosphor film on a portion of a top surface of the LED chip, an area of the phosphor film being smaller than an area of the top surface of the LED chip; and
a molding body covering a remaining portion of the top surface of the LED chip that is not covered with the phosphor film, a side surface of the LED chip, and a side surface of the phosphor film.

13. The LED package of claim 12, wherein the molding body includes a white resin.

14. The LED package of claim 12, wherein the molding body includes reflective powder.

15. The LED package of claim 12, wherein
the top surface of the LED chip includes a first region overlapping the phosphor film and a second region overlapping the molding body, and
the LED chip is configured to emit light through only the first region.

16. A light-emitting diode (LED) package comprising:
a LED chip;
a phosphor film on a top surface of the LED chip; and
a molding structure connected to a side surface of the LED chip.

17. The LED package of claim 16, further comprising:
electrodes connected to the LED chip, wherein
the molding structure is a molding phosphor that contacts side surfaces and a bottom surface of the LED chip,
the molding phosphor defines openings that expose the LED chip,
the electrodes are connected to the LED chip through the openings,
the phosphor film and the molding phosphor are configured to convert light generated by the LED chip into white light,
the phosphor film extends onto a top surface of the molding phosphor, and
a thickness of the phosphor film is uniform.

18. The LED package of claim 16, further comprising:
electrodes connected to the LED chip, wherein
the molding structure is a molding phosphor that contacts side surfaces and a bottom surface of the LED chip,
the molding phosphor defines openings that expose the LED chip,
the electrodes are connected to the LED chip through the openings,
the phosphor film and the molding phosphor are configured to convert light generated by the LED chip into white light,
an area of the phosphor film is greater than an area of the top surface of the LED chip, and
a thickness of the phosphor film is uniform.

19. The LED package of claim 16, further comprising:
electrodes connected to the LED chip, wherein
the molding structure is a molding body covering a remaining portion of the top surface of the LED chip, a side surface of the LED chip, and a side surface of the phosphor film,
the molding body defines openings that expose the LED chip,
the electrodes are connected to the LED chip through the openings,
the phosphor film is configured to convert light generated by the LED chip into white light,
an area of the phosphor film is less than an area of the top surface of the LED chip, and
a thickness of the phosphor film is uniform.

20. The LED package of claim 16, wherein the phosphor film includes a wavelength conversion material.
